(19) United States
(12) Patent Application Publication
(10) Pub. No.: US 2008/0067590 A1
(43) Pub. Date: Mar. 20, 2008

(54) Semiconductor device and manufacturing method of the same

(75) Inventors: Nobuyuki Mise, Tokyo (JP); Kunihiko Iwamoto, Kyoto (JP); Yukimune Watanabe, Tsukuba (JP); Shinji Migita, Tsukuba (JP)

Correspondence Address: Stanley P. Fisher;Reed Smith LLP, Suite 1400, 3110 Fairview Park Drive, Falls Church, VA, 22042-4503, US

(73) Assignees: Renesas Technology Corp.; Rohm Co., Ltd.; Seiko Epson Corporation; National Institute of Advanced Industrial Science and Technology

(21) Appl. No.: 11/798,277

(22) Filed: May 11, 2007

(30) Foreign Application Priority Data
May 12, 2006 (JP) JP2006-133213

(51) Int. Cl. H01L 27/12; H01L 21/3205

(52) U.S. Cl. 257/347; 438/595; 257/E27.112; 257/E21.294

(57) ABSTRACT

It is an object of the present invention to provide a technology which can form a sidewall without deteriorating device characteristics. A gate insulating film formed of a high dielectric constant film and a polysilicon film are formed on a semiconductor substrate. By patterning the polysilicon film, silicon gate electrodes are formed. Subsequently, a laminated film of an aluminum oxide film and a silicon nitride film is formed on the semiconductor substrate. Thereafter, the silicon nitride film is anisotropically dry-etched to leave silicon nitride films only on sidewalls of the silicon gate electrodes. At this time, the aluminum oxide film formed under the silicon nitride film functions as an etching stopper. Then, the exposed aluminum oxide film is wet-etched using diluted hydrofluoric acid.

### CROSS-REFERENCE TO RELATED APPLICATION

The present application claims priority from Japanese Patent Application No. JP2006-133213 filed on May 12, 2006, the content of which is hereby incorporated by reference into this application.

### TECHNICAL FIELD OF THE INVENTION

The present invention relates to a semiconductor device and a manufacturing technology thereof. More particularly, it relates to a technology effectively applied to a semiconductor device and a manufacturing method thereof in which a semiconductor substrate thereof is prevented from being etched.

### BACKGROUND OF THE INVENTION

Japanese Patent Application Laid-Open Publication No. 7-115188 (paragraphs 0030 to 0031 and FIG. 1) (Patent Document 1) discloses a technology in which a sidewall is formed of a first sidewall made of an aluminum oxide film and a second sidewall made of a silicon nitride film in order to improve high-frequency characteristics between a gate electrode and a drain region.

Japanese Patent Application Laid-Open Publication No. 2003-338507 (paragraphs 0012 to 0017 and FIG. 1) (Patent Document 2) discloses a technology in which a sidewall is formed of a first sidewall made of an aluminum oxide film and a second sidewall made of a silicon nitride film in order to suppress a short channel effect of a MIS (Metal Insulator Semiconductor) transistor and realize a high-speed signal operation.

Further, IEEE international ELECTRON DEVICES meeting 2005 (IEDM 05-69 to IEDM 05-72) (Non-Patent Document 1) discloses a laminated sidewall.

### SUMMARY OF THE INVENTION

In a semiconductor device such as a MISFET (Metal Insulator Semiconductor Field Effect Transistor), in order to suppress a short channel effect and form a low-resistance source region and a low-resistance drain region, a shallow impurity diffusion region aligned with a thin sidewall must be formed near a gate, and a deep impurity region aligned with a thick sidewall must be formed at a position apart from the gate.

For example, the sidewalls described above are formed by forming a silicon oxide film on a semiconductor substrate including an upper surface of the gate electrode, and then performing the anisotropic dry etching so as to leave the silicon oxide film only on the sidewalls of the gate electrode. In this case, the sidewalls have an important function to define the widths of impurity regions constituting the source region and the drain region. Therefore, since the width of the sidewall must be approximated to a design value as much as possible, the silicon oxide film is etched excessively or overetched in the anisotropic dry etching to form the sidewall. More specifically, when the etching is insufficient, a bottom end of the sidewall is not patterned appropriately and the width of the sidewall deviates from the design value. For this reason, overetching is performed so as to appropriately pattern the bottom end of the sidewall.

However, when the overetching is performed, a surface of the semiconductor substrate made of silicon is also etched. In other words, in a region outside the sidewall formed on the sidewall of the gate electrode, the semiconductor substrate is etched. In this region, an impurity is doped to form a deep impurity diffusion region. However, since the semiconductor substrate is etched, the thickness of the deep impurity diffusion region is reduced. When the thickness of the deep impurity diffusion region to be a part of the source region or the drain region decreases, there occurs a problem that the resistance of the source region and the drain region increases. Furthermore, after ions are implanted into the deep impurity diffusion region, heat treatment is performed to activate the implanted impurity. This heat treatment has a function to recover a crystal defect caused by the impurity ion implantation. In the recovery from the crystal defect, the crystal is recovered on the basis of a crystal region in which crystal is not broken. Therefore, when the semiconductor substrate is etched, a region in which ions are not implanted decreases, and the crystal region in which ions are not implanted and crystal is not broken decreases. Accordingly, since a crystal region to be a base for the recovery of crystal is small, it becomes difficult to recover the crystal defect.

The problems described above are considered to occur when a usual semiconductor substrate made of silicon is used. In particular, when an SOI (Silicon On Insulator) substrate having a thin silicon layer is used, these problems become more conspicuous. In the SOI substrate, a buried insulating film is formed in a semiconductor substrate, and a very thin (about 5 nm) silicon layer is formed on the buried insulating film. Also, ions are implanted into the silicon layer to form a source region and a drain region. Therefore, when the silicon layer is etched by the overetching in the process of forming the sidewalls, the very thin silicon layer further decreases in thickness, and the resistance of the source region and the drain region increases. More specifically, in the SOI substrate, the silicon layer is not desired to be etched even by 1 nm.

On the other hand, if overetching is not performed to prevent the semiconductor substrate from being etched, the bottom end of the sidewall is not patterned appropriately as described above, and the width of the sidewall deviates from the design value. In this case, there occurs the problem that the widths of sidewalls of the semiconductor devices fluctuate, and thus device characteristics are apt to fluctuate.

In recent years, due to the further miniaturization of a MISFET, a thin gate insulating film has been required. Also, although a silicon oxide film has been used as a gate insulating film in general, due to the reduction in film thickness, the leakage current tunneling through the gate insulating film has become unignorable.

Therefore, the use of a high dielectric constant film which can increase the physical thickness without changing the capacitance has been examined. When the high dielectric constant film having a dielectric constant higher than that of a silicon oxide film is used, the physical thickness can be increased without changing the capacitance. For this reason, a leakage current due to a tunnel current can be reduced. Further, due to the miniaturization of a MISFET, a gate length of a gate electrode has become small.

When the gate electrode and the gate insulating film formed of a high dielectric constant film as described above are used, there occurs a problem that silicon oxide films are formed on the upper and lower interfaces of the high dielectric constant film in particular due to processes such as a sidewall forming process and a heat treatment process. This is a phenomenon which is not observed when a silicon oxide film is used as a gate insulating film. More specifically, when the high dielectric constant film is used as the gate insulating film to reduce the gate length of the gate electrode, the silicon oxide films are formed on the upper and lower interfaces of the high dielectric constant film due to the processes, and the thickness of the gate insulating film increases substantially. When the thickness of the gate insulating film increases, an equivalent oxide thickness (EOT) increases, and a drive current flowing between the source region and the drain region cannot be obtained. Furthermore, when the thickness of the gate insulating film increases, a short channel effect becomes more conspicuous, and threshold voltages of MISFETs are apt to fluctuate. The problems described above are caused because unnecessary silicon oxide films are formed on the upper and lower interfaces of the high dielectric constant film, and this phenomenon conspicuously appears when the gate length is set at, for example, 20 nm or less, especially, 10 nm or less.

As described above, it can be understood that, when a sidewall is formed, various problems causing the deterioration of device characteristics occur.

An object of the present invention is to provide a technology capable of forming a sidewall without deteriorating device characteristics.

The above and other objects and novel characteristics of the present invention will be apparent from the description of this specification and the accompanying drawings.

The typical ones of the inventions disclosed in this application will be briefly described as follows.

A semiconductor device according to the present invention comprises: a semiconductor substrate; a gate insulating film formed on the semiconductor substrate; a gate electrode formed on the gate insulating film; and a sidewall formed on a sidewall of the gate electrode. Also, the sidewall is formed of a laminated film of an aluminum oxide film and an insulating film, and the aluminum oxide film is in contact with the semiconductor substrate and the insulating film is not in contact with the semiconductor substrate.

Further, a manufacturing method of a semiconductor device according to the present invention comprises: (a) a step of forming a gate insulating film on a semiconductor substrate; (b) a step of forming a gate electrode on the gate insulating film; and (c) a step of forming a sidewall on a sidewall of the gate electrode. Also, the step (c) includes: (c1) a step of forming an aluminum oxide film on the semiconductor substrate including the gate electrode; (c2) a step of forming an insulating film on the aluminum oxide film; (c3) a step of leaving the insulating film only on a sidewall of the gate electrode; and (c4) a step of removing the aluminum oxide film exposed by performing the step (c3).

The effects obtained by typical aspects of the present invention will be briefly described below.

A sidewall formed on a sidewall of a gate electrode is formed of a laminated film of an aluminum oxide film and an insulating film. By this means, since the aluminum oxide film functions as an etching stopper when the insulating film is etched, it is possible to prevent a semiconductor substrate from being etched. Also, since an aluminum oxide film is formed on the sidewall of the gate electrode, it is possible to prevent unnecessary silicon oxide films from being formed on the upper and lower interfaces of a high dielectric constant film in such processes as a sidewall forming step.

### BRIEF DESCRIPTIONS OF THE DRAWINGS

FIG. 1 is a sectional view showing a structure of a semiconductor device according to a first embodiment of the present invention;

FIG. 2 is a sectional view showing a manufacturing process of the semiconductor device according to the first embodiment;

FIG. 3 is a sectional view showing the manufacturing process of the semiconductor device subsequent to FIG. 2;

FIG. 4 is a sectional view showing the manufacturing process of the semiconductor device subsequent to FIG. 3;

FIG. 5 is a sectional view showing the manufacturing process of the semiconductor device subsequent to FIG. 4;

FIG. 6 is a sectional view showing the manufacturing process of the semiconductor device subsequent to FIG. 5;

FIG. 7 is a sectional view showing the manufacturing process of the semiconductor device subsequent to FIG. 6;

FIG. 8 is a sectional view showing the manufacturing process of the semiconductor device subsequent to FIG. 7;

FIG. 9 is a sectional view showing the manufacturing process of the semiconductor device subsequent to FIG. 8;

FIG. 10 is a sectional view showing the manufacturing process of the semiconductor device subsequent to FIG. 9;

FIG. 11 is a sectional view showing the manufacturing process of the semiconductor device subsequent to FIG. 10;

FIG. 12 is a sectional view showing the manufacturing process of the semiconductor device subsequent to FIG. 11;

FIG. 13 is a sectional view showing the manufacturing process of the semiconductor device subsequent to FIG. 12;

FIG. 14 is a sectional view showing the manufacturing process of the semiconductor device subsequent to FIG. 13;

FIG. 15 is a sectional view showing the manufacturing process of the semiconductor device subsequent to FIG. 14;

FIG. 16 is a sectional view showing the manufacturing process of the semiconductor device subsequent to FIG. 15;

FIG. 17 is a sectional view showing the manufacturing process of the semiconductor device subsequent to FIG. 16;

FIG. 18 is a sectional view showing the manufacturing process of the semiconductor device subsequent to FIG. 17;

FIG. 19 is a sectional view showing the manufacturing process of the semiconductor device subsequent to FIG. 18;

FIG. 20 is a sectional view showing the manufacturing process of the semiconductor device subsequent to FIG. 19;

FIG. 21 is a sectional view showing the manufacturing process of the semiconductor device subsequent to FIG. 20;

FIG. 22 is a sectional view showing a manufacturing process of a semiconductor device according to a second embodiment;

FIG. 23 is a sectional view showing the manufacturing process of the semiconductor device subsequent to FIG. 22;

FIG. 24 is a sectional view showing the manufacturing process of the semiconductor device subsequent to FIG. 23;

FIG. 25 is a sectional view showing the manufacturing process of the semiconductor device subsequent to FIG. 24;

FIG. 26 is a sectional view showing the manufacturing process of the semiconductor device subsequent to FIG. 25;

FIG. 27 is a sectional view showing the manufacturing process of the semiconductor device subsequent to FIG. 26; and

FIG. 28 is a sectional view showing the manufacturing process of the semiconductor device subsequent to FIG. 27.

### DESCRIPTIONS OF THE PREFERRED EMBODIMENTS

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof.

Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle.

Similarly, in the embodiments described below, when the shape of the components, positional relation thereof, and the like are mentioned, the substantially approximate and similar shapes and the like are included therein unless otherwise stated or except the case where it can be conceived that they are apparently excluded in principle. The same goes for the numerical value and the range described above.

Also, components having the same function are denoted by the same reference symbols throughout the drawings for describing the embodiments, and the repetitive description thereof is omitted.

### First Embodiment

As a semiconductor device according to a first embodiment, a CMISFET (Complementary MISFET) in which an n channel MISFET and a p channel MISFET are formed on one semiconductor substrate will be exemplified.

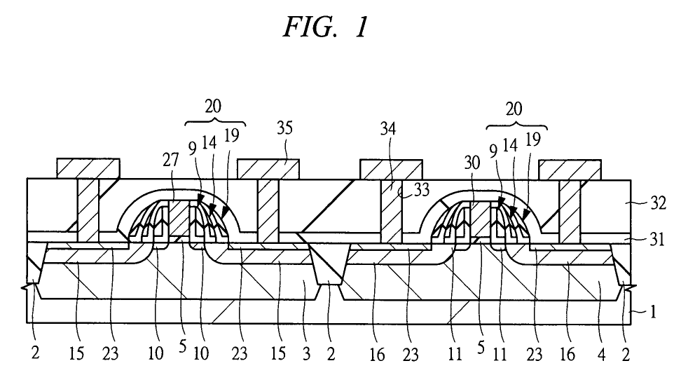

FIG. 1 is a sectional view showing a structure of a CMISFET according to the first embodiment. In FIG. 1, the left MISFET indicates an n channel MISFET and the right MISFET indicates a p channel MISFET.

As shown in FIG. 1, an element isolation region 2 is formed in a main surface (element forming surface) of a semiconductor substrate 1 made of single crystal silicon. In an active region isolated by the element isolation region 2, a well serving as a semiconductor region is formed. In the active region, a p type well 3 implanted with a p type impurity such as boron (B) is formed in the semiconductor substrate 1 in an n channel MISFET forming region. Similarly, in the active region, an n type well 4 implanted with an n type impurity such as phosphorous (P) or arsenic (As) is formed in the semiconductor substrate 1 in a p channel MISFET forming region.

Next, the structure of the n channel MISFET formed on the p type well 3 will be described below. First, the n channel MISFET has a gate insulating film 5 on the p type well 3, and a gate electrode 27 is formed on the gate insulating film 5. The gate insulating film 5 is formed of, for example, a high dielectric constant film having a dielectric constant higher than that of a silicon oxide film. As the high dielectric constant film, for example, a hafnium oxide film or the like is used. Although the gate insulating film 5 is formed of a high dielectric constant film in this case, it is not meant to be restrictive, and a silicon oxynitride film or a silicon oxide film can be used to form the gate insulating film 5.

The gate electrode 27 is formed of a metal silicide film, for example, a nickel silicide film. Alternatively, the gate electrode 27 can be formed of a metal film or a polysilicon film. In the first embodiment, the gate length of the gate electrode 27 is scaled down to 10 nm or less.

Sidewalls 20 are formed on both the sidewalls of the gate electrode 27. The sidewall 20 is formed so that a source region and a drain region of an n channel MISFET are formed from a shallow impurity diffusion region and a deep impurity diffusion region. More specifically, in the semiconductor substrate 1 under the sidewall 20, a shallow n type impurity diffusion region 10 is formed, and a deep n type impurity diffusion region 15 is formed outside the shallow n type impurity diffusion region 10.

The shallow n type impurity diffusion region 10 and the deep n type impurity diffusion region 15 are semiconductor regions implanted with an n type impurity such as phosphorus or arsenic, and an n type impurity is implanted in the deep n type impurity diffusion region 15 more deeply than in the shallow n type impurity diffusion region 10.

The source region and the drain region are formed from the shallow n type impurity diffusion region 10 and the deep n type impurity diffusion region 15. In other words, by forming the shallow n type impurity diffusion region 10 under the end portion of the gate electrode 27, it becomes possible to suppress a field concentration under the end portion of the gate electrode 27.

For example, a nickel silicide film 23 is formed on the deep n type impurity diffusion region 15. The nickel silicide film 23 is formed to reduce the resistance of the source region or the drain region including the deep n type impurity diffusion region 15. In place of the nickel silicide film 23, a cobalt silicide film or a titanium silicide film may be formed. In this manner, an n channel MISFET is formed.

Next, the structure of the p channel MISFET formed on the n type well 4 will be described below. First, the p channel MISFET has a gate insulating film 5 on the n type well 4, and a gate electrode 30 is formed on the gate insulating film 5. The gate insulating film 5 is formed of, for example, a high dielectric constant film having a dielectric constant higher than that of a silicon oxide film. As the high dielectric constant film, for example, a hafnium oxide film or the like is used. Although the gate insulating film 5 is formed of a high dielectric constant film in this case, it is not meant to be restrictive, and a silicon oxynitride film or a silicon oxide film can be used to form the gate insulating film 5.

The gate electrode 30 is formed of a metal silicide film, for example, a nickel silicide film. Also, the gate electrode 30 can be formed of a metal film or a polysilicon film. In the first embodiment, the gate length of the gate electrode 30 is scaled down to 20 nm or less, more desirably, 10 nm or less.

Sidewalls 20 are formed on both the sidewalls of the gate electrode 30. The sidewall 20 is formed so that a source region and a drain region of a p channel MISFET are formed from a shallow impurity diffusion region and a deep impurity diffusion region. More specifically, in the semiconductor substrate 1 under the sidewall 20, a shallow p type impurity diffusion region 11 is formed, and a deep p type impurity diffusion region 16 is formed outside the shallow p type impurity diffusion region 11.

The shallow p type impurity diffusion region 11 and the deep p type impurity diffusion region 16 are semiconductor regions implanted with a p type impurity such as boron, and the p type impurity is implanted in the deep p type impurity diffusion region 16 more deeply than in the shallow p type impurity diffusion region 11.

The source region and the drain region are formed from the shallow p type impurity diffusion region 11 and the deep p type impurity diffusion region 16. In other words, by forming the shallow p type impurity diffusion region 11 under the end portion of the gate electrode 30, it becomes possible to suppress a field concentration under the end portion of the gate electrode 30.

For example, a nickel silicide film 23 is formed on the deep p type impurity diffusion region 16. The nickel silicide film 23 is formed to reduce the resistance of the source region or the drain region including the deep p type impurity diffusion region 16. In place of the nickel silicide film 23, a cobalt silicide film or a titanium silicide film may be formed. In this manner, a p channel MISFET is formed.

Then, an interlayer insulating film formed of a laminated film of a silicon nitride film 31 and a silicon oxide film 32 is formed on the n channel MISFET and the p channel MISFET. Also, contact holes 33 are formed in the interlayer insulating film, and plugs 34 are formed by filling the contact holes 33. The plug 34 is formed of, for example, a laminated film of a titanium/titanium nitride film which is a barrier conductor film and a tungsten film. A wiring 35 is formed on the silicon oxide film 32 in which the plugs 34 are formed. The wiring 35 is formed of, for example, a laminated film of a titanium/titanium nitride film, an aluminum film, and a titanium/titanium nitride film. In the first embodiment, the case where the wiring 35 is formed of an aluminum film has been described. However, it is not meant to be restrictive, and the wiring 35 may be formed of a copper wiring by a Damascene Method.

Next, a characteristic structure of the present invention will be described below. Since the characteristic structure of the present invention is common in an n channel MISFET and a p channel MISFET, the description will be made using the n channel MISFET as an example. In the n channel MISFET, one characteristic feature of the present invention lies in the structure of the sidewall 20. As is apparent from FIG. 1, the sidewall 20 is formed of a first laminated film 9, a second laminated film 14, and a third laminated film 19. More specifically, the sidewall 20 according to the first embodiment is formed of multiple layers in units of laminated films.

In the sidewall 20 according to the first embodiment, the first laminated film 9 is formed on a sidewall of the gate electrode 27, and the second laminated film 14 is formed outside the first laminated film 9. Then, the third laminated film 19 is formed outside the second laminated film 14. In alignment with the sidewall 20 formed as described above, the shallow n type impurity diffusion region 10, the deep n type impurity diffusion region 15 and the nickel silicide film 23 are formed. In other words, in alignment with the innermost first laminated film 9, the shallow n type impurity diffusion region 10 is formed, and the deep n type impurity diffusion region 15 is formed in alignment with the second laminated film 14. Further, the nickel silicide film 23 is formed in alignment with the third laminated film 19.

In the first embodiment, as will be described in a manufacturing method later in detail, the widths of the first laminated film 9, the second laminated film 14, and the third laminated film 19 can be controlled with high accuracy. For this reason, positions where the shallow n type impurity diffusion region 10, the deep n type impurity diffusion region 15, and the nickel silicide film 23 formed in alignment with the respective laminated films can be accurately matched with design values. Accordingly, the variation in electrical characteristics among the plurality of elements can be suppressed.

Next, a structure of each laminated film which is one of the characteristic features of the present invention will be described below. Each laminated film has a laminated structure of an aluminum oxide film and an insulating film. The insulating film is formed of, for example, a silicon nitride film, but a silicon oxide film may be used. In each laminated film, an aluminum oxide film is formed as a lower layer, and a silicon nitride film is formed on the aluminum oxide film. More specifically, the aluminum oxide film is in contact with the semiconductor substrate 1, and the silicon nitride film is designed not to be in contact with the semiconductor substrate 1. In other words, in each laminated film, the aluminum oxide film has an L-shape, and the silicon nitride film is formed on the L-shaped aluminum oxide film. In this structure, as will be described in the manufacturing method later in detail, the semiconductor substrate 1 can be prevented from being etched in the etching process to form the respective laminated films. In short, the silicon nitride film is removed by dry etching, and at this time, since the aluminum oxide film formed below the silicon nitride film has high resistance to the dry etching, the aluminum oxide film functions as an etching stopper. More specifically, since the aluminum oxide film functions as the etching stopper, it is possible to prevent the semiconductor device 1 below the aluminum oxide film from being etched. Since the semiconductor substrate 1 can be prevented from being etched, the source region and the drain region formed in the semiconductor substrate 1 can have sufficient thicknesses. When the semiconductor substrate 1 is etched, the source region and the drain region decrease in thickness, and there occurs a problem that the resistance of the source region or the drain region increases. However, according to the sidewall 20 of the first embodiment, the semiconductor substrate 1 can be prevented from being etched when the respective laminated films constituting the sidewall 20 are formed. Therefore, it is possible to suppress the increase of the resistance of the source region or the drain region.

Furthermore, after the impurity ions are implanted, heat treatment is performed in the source region and the drain region so as to activate the implanted impurity. The heat treatment has a function to recover the crystal defect caused by the ion implantation of the impurity. The crystal defect is recovered on the basis of a crystal region in which crystal is not broken. Therefore, if the semiconductor substrate is etched, a region in which ions are not implanted decreases, and a crystal region in which ion implantation is not performed and crystal is not broken decreases. Accordingly, since the crystal region serving as the base of the crystal recovery is small, the recovery from the crystal defect becomes difficult. However, in the first embodiment, since the semiconductor substrate 1 can be prevented from being etched in the step of forming the sidewall 20, the above-mentioned disadvantages can be avoided.

Further, if a high dielectric constant film is used as the gate insulating film 5, silicon oxide films are formed on the upper and lower interfaces of the high dielectric constant film in the step of forming the sidewall 20 and other heat treatment steps. When such a problem occurs, the thickness of the gate insulating film increases substantially. When the thickness of the gate insulating film increases, an equivalent oxide thickness (EOT) increases, there occurs a problem that a drive current flowing between the source region and the drain region cannot be obtained. Furthermore, when the thickness of the gate insulating film increases, a short channel effect becomes conspicuous, and the threshold voltage of the MISFETs is apt to fluctuate. However, in the first embodiment, the first laminated film 9 constituting the sidewall 20 is formed of the laminated film of an aluminum oxide film and a silicon nitride film, and the aluminum oxide film is designed to be in contact with the gate electrode 27 and the gate insulating film 5. The aluminum oxide film has a barrier property that suppresses oxygen from passing through the aluminum oxide film. Therefore, in the step of forming the sidewall 20 and the following heat treatment step, the supply of oxygen to the gate insulating film 5 formed of the high dielectric constant film can be blocked by the aluminum oxide film. For this reason, it is possible to prevent silicon oxide films from being formed on the upper and lower interfaces of the high dielectric constant film.

The semiconductor device according to the first embodiment has the structure as described above, and a manufacturing method of the semiconductor device according to the first embodiment will be described below with reference to the accompanying drawings.

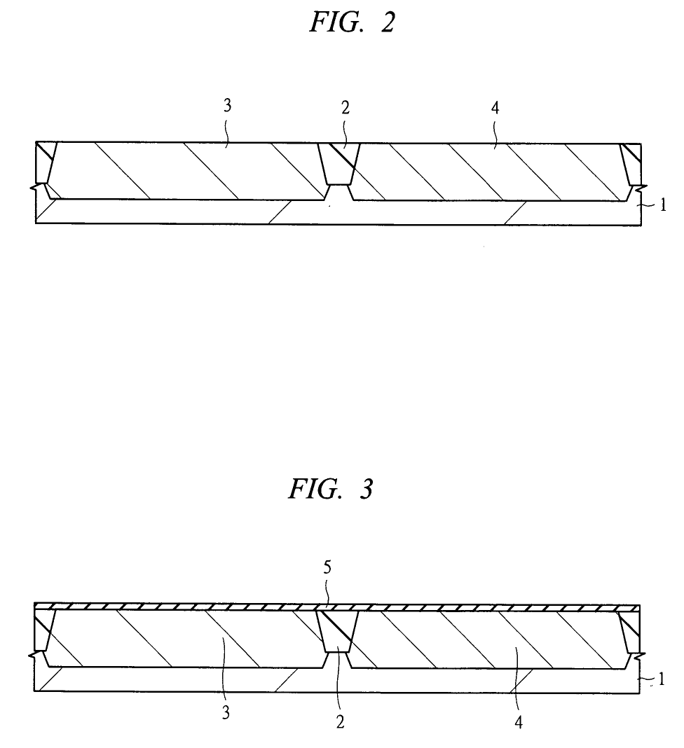

As shown in FIG. 2, a semiconductor substrate 1 made of single crystal silicon to which a p type impurity such as boron (B) is implanted is prepared. At this time, the semiconductor substrate 1 is in a state of a semiconductor wafer having a nearly disk-like shape. Then, the element isolation region 2 which isolates elements from each other is formed on a main surface of the semiconductor substrate 1. The element isolation region 2 is formed so that respective elements do not interfere with each other. The element isolation region 2 can be formed by using, for example, a LOCOS (Local Oxidation of Silicon) method or an STI (Shallow Trench Isolation) method. In FIG. 1, the element isolation region 2 formed by the STI method is shown. In the STI method, the element isolation region 2 is formed in the manner described below. That is, an element isolation trench is formed in the semiconductor substrate 1 by a photolithography technology and an etching technology. Then, a silicon oxide film is formed on the semiconductor substrate 1 so as to fill the element isolation trench. Thereafter, by a chemical mechanical polishing method (CMP), an unnecessary silicon oxide film formed on the semiconductor substrate 1 is removed. In this manner, the element isolation region 2 in which the silicon oxide film is buried only in the element isolation trench can be formed.

Next, an impurity is implanted into an active region isolated by the element isolation region 2, thereby forming a well. For example, the p type well 3 is formed in an n channel MISFET forming region in the active region, and the n type well 4 is formed in a p channel MISFET forming region. The p type well 3 is formed by implanting a p type impurity such as boron into the semiconductor substrate 1 by an ion implantation method. Similarly, the n type well 4 is formed by implanting an n type impurity such as phosphorous (P) or arsenic (As) into the semiconductor substrate 1 by an ion implantation method.

Subsequently, semiconductor regions for forming channels are formed in surface areas of the p type well 3 and the n type well 4. The semiconductor region for forming channel is formed to adjust a threshold voltage for forming the channel. For example, a p type impurity such as boron is implanted into the surface area of the p type well 3, and an n type impurity such as phosphorous or arsenic is implanted into the surface area of the n type well 4. In this manner, semiconductor regions for forming channels can be formed in the surface areas of the p type well 3 and the n type well 4.

Next, as shown in FIG. 3, the gate insulating film 5 is formed on the semiconductor substrate 1. The gate insulating film 5 is formed of, for example, a high dielectric constant film having a dielectric constant higher than that of a silicon oxide film. In terms of high insulation resistance and excellent electrical and physical stability at a silicon-silicon oxide interface, a silicon oxide film has been used as the gate insulating film 5. However, due to the further miniaturization of an element, the gate insulating film 5 is required to have a very small film thickness. In particular, in the first embodiment, a gate length of the gate electrode is designed to have 10 nm or less. Therefore, along with the miniaturization of the gate electrode, the film thickness of the gate insulating film 5 formed under the gate electrode must be reduced. If the thin silicon oxide film is used as the gate insulating film 5 as described above, electrons flowing in the channel of the MISFET tunnel through a barrier formed of the silicon oxide film and then flow into the gate electrode, that is, a so-called tunnel current is generated.

For its solution, a material having a dielectric constant higher than that of a silicon oxide film, that is, a high dielectric constant film which can increase the physical film thickness without changing the capacitance has been used. When the high dielectric constant film is used, since the physical film thickness can be increased without changing the capacitance, a leakage current can be reduced.

For example, as the high dielectric constant film, a hafnium oxide film (HfO₂ film) which is one of hafnium oxides is used. However, in place of the hafnium oxide film, another hafnium-based insulating film such as a hafnium aluminate film, an HfON film (hafnium oxynitride film), an HfSiO film (hafnium silicate film), an HfSiON film (hafnium silicon oxynitride film), or an HfAlO film can be used. Furthermore, a hafnium-based insulating film obtained by implanting an oxide such as tantalum oxide, niobium oxide, titanium oxide, zirconium oxide, lanthanum oxide, or yttrium oxide into the hafnium-based insulating film can be used. Similar to the hafnium oxide film, the hafnium-based insulating film has a dielectric constant higher than that of a silicon oxide film or a silicon oxynitride film. Therefore, the same effect as that in the case of using the hafnium oxide film can be obtained.

As described above, it is desired that the high dielectric constant film is used as the gate insulating film 5. However, for example, a silicon oxide film may be used. At this time, the silicon oxide film can be formed by using, for example, a thermal oxidation method. Also, the gate insulating film 5 may be formed of a silicon oxynitride film (SiON). More specifically, a structure in which nitrogen is segregated at the interface between the gate insulating film 5 and the semiconductor substrate 1 can be used. The silicon oxynitride film can effectively suppress the generation of an interface state in a film and reduce electron traps in comparison with the silicon oxide film. Therefore, the hot carrier resistance of the gate insulating film 5 can be improved, and the insulation resistance can be improved. Further, the penetration of the impurity through the silicon oxynitride film is more difficult than the penetration of the impurity through the silicon oxide film. For this reason, when the silicon oxynitride film is used as the gate insulating film 5, a variation in threshold voltage caused by the diffusion of the impurity in the gate electrode to the semiconductor substrate 1 side can be suppressed. The silicon oxynitride film can be formed by the thermal treatment of the semiconductor substrate 1 in an atmosphere containing nitrogen such as NO, NO₂, or NH₃. Alternatively, after the gate insulating film 5 formed of a silicon oxide film is formed on the surface of the semiconductor substrate 1, the semiconductor substrate 1 is thermally treated in an atmosphere containing nitrogen so that nitrogen is segregated at the interface between the gate insulating film 5 and the semiconductor substrate 1. By this means, the same effect can be obtained.

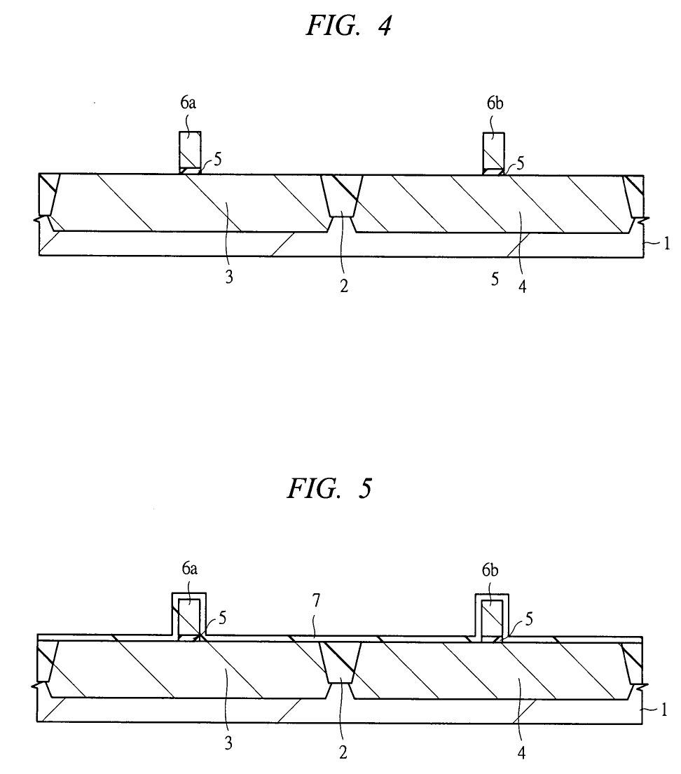

Subsequently, a polysilicon film is formed on the gate insulating film 5. The polysilicon film can be formed by, for example, a CVD (Chemical Vapor Deposition) method. Thereafter, the polysilicon film is patterned by using a photolithography technology and an etching technology, thereby forming silicon gate electrodes 6a and 6b as shown in FIG. 4. The gate lengths of the silicon gate electrodes 6a and 6b are, for example, 20 nm or less, desirably, 10 nm or less. More specifically, the silicon gate electrodes 6a and 6b formed in the first embodiment are miniaturized.

Next, as shown in FIG. 5, an aluminum oxide film 7 is formed on the semiconductor substrate 1 on which the silicon gate electrodes 6a and 6b are formed. The aluminum oxide film 7 can be formed by using, for example, an ALD (Atomic Layer Deposition) method. The temperature at which the aluminum oxide film is formed by the ALD method ranges from 100° C. to 500° C., desirably, 200° C. to 300° C. Therefore, since the aluminum oxide film 7 can be formed at a relatively low temperature, it is possible to prevent silicon oxide films from being formed on the upper and lower interfaces of the high dielectric constant film constituting the gate insulating film 5 in the step of forming the aluminum oxide film 7. Furthermore, since the aluminum oxide film 7 has low permeability of oxygen and nitrogen, the aluminum oxide film 7 is formed to be in contact with the gate insulating film 5. By doing so, in the later heat treatment step or the like, the supply of oxygen to the gate insulating film 5 can be suppressed. In other words, the supply of oxygen generated in the later steps can be suppressed by forming the aluminum oxide film 7. Accordingly, the reaction between the high dielectric constant film and the oxygen can be suppressed, and it is possible to prevent silicon oxide films from being formed on the upper and lower interfaces of the high dielectric constant film. Therefore, the increase of the substantial physical film thickness of the gate insulating film 5 can be suppressed, and the decrease of the drain current can be suppressed. More specifically, it becomes possible to improve the electric characteristics of the MISFET. As described above, the aluminum oxide film 7 has an advantage of being capable of forming the aluminum oxide film 7 itself at a relatively low temperature and an advantage of being capable of suppressing the supply of oxygen and nitrogen to the gate insulating film 5. Further, the film thickness of the aluminum oxide film 7 is about 1 nm to 4 nm.

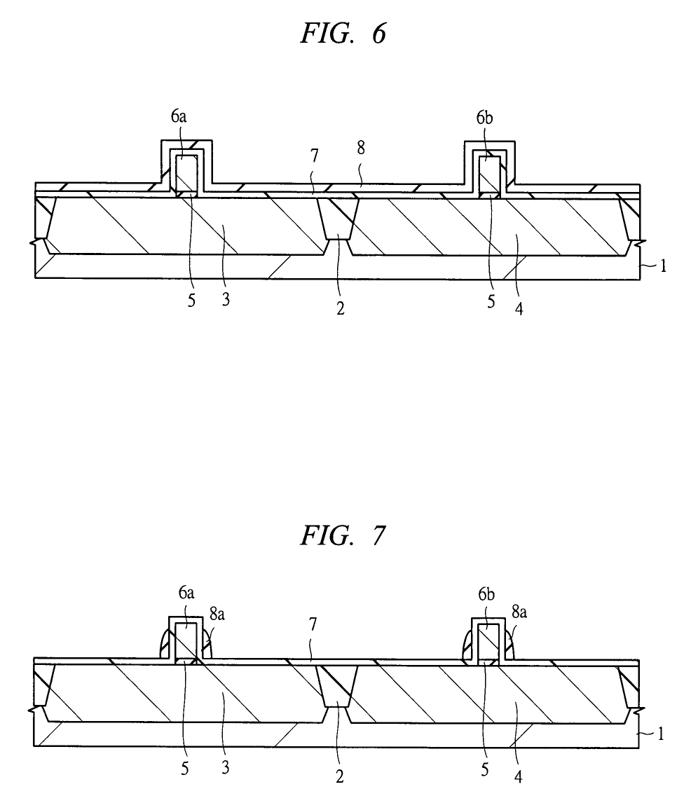

Subsequently, as shown in FIG. 6, a silicon nitride film 8 is formed on the aluminum oxide film 7. The silicon nitride film 8 can be formed by using, for example, a CVD method. An insulating film formed on the aluminum oxide film 7 is not limited to the silicon nitride film 8. For example, a silicon oxide film may be formed. More specifically, any insulating film can be formed on the aluminum oxide film 7 as long as it can be dry-etched easily. Further, the film thickness of the silicon nitride film 8 is about 1 nm to 5 nm.

Next, as shown in FIG. 7, the silicon nitride film 8 is removed by anisotropic dry etching. By doing so, silicon nitride films 8a are left only on the sidewalls of the silicon gate electrodes 6a and 6b. In this case, in the anisotropic dry etching for the silicon nitride film 8, the underlying aluminum oxide film 7 is exposed. Since the aluminum oxide film 7 is a film having high resistance to dry etching, the aluminum oxide film 7 is not removed. In other words, the aluminum oxide film 7 functions as an etching stopper in the dry etching for removing the silicon nitride film 8. For this reason, the semiconductor substrate 1 under the aluminum oxide film 7 is not etched by the dry etching. Since the semiconductor substrate 1 is made of silicon, if the aluminum oxide film 7 is not formed, the semiconductor substrate 1 is etched in the dry etching for the silicon nitride film 8. In particular, in order to approximate the widths of the silicon nitride films 8a formed on the sidewalls of the silicon gate electrodes 6a and 6b, the silicon nitride film 8 is overetched in the dry etching thereof. More specifically, if the dry etching for the silicon nitride film 8 is insufficient, the bottom ends of the silicon nitride films 8a formed on the sidewalls of the silicon gate electrodes 6a and 6b are not patterned appropriately, and the widths of the silicon nitride films 8a significantly deviate from the design values. For its prevention, the silicon nitride film 8 is overetched in the dry etching thereof. However, if the silicon nitride film 8 is overetched in the dry etching thereof, silicon of the semiconductor substrate 1 is exposed in the regions except for the sidewalls of the silicon gate electrodes 6a and 6b, and the exposed silicon is etched.

When the semiconductor substrate 1 is etched, the thickness of the source region and the drain region formed in the subsequent steps decreases, which causes the increase of the resistance of the source region and the drain region. Furthermore, after an impurity is ion-implanted, the thermal treatment is performed to activate the implanted impurity in the source region and the drain region. This thermal treatment has a function to recover the crystal defect caused by the ion implantation of the impurity. In the recovery from the crystal defect, the crystal is recovered on the basis of a crystal region in which crystal is not broken. Therefore, when the semiconductor substrate is etched, a region in which ions are not implanted decreases, and the crystal region in which ions are not implanted and crystal is not broken decreases. Accordingly, since a crystal region to be a base for the recovery of crystal is small, it becomes difficult to recover the crystal defect. For this reason, it is desired that the semiconductor substrate 1 itself is not etched in the dry etching for the silicon nitride film 8.

Therefore, in the first embodiment, the aluminum oxide film 7 is formed between the semiconductor substrate 1 and the silicon nitride film 8. By this means, even though the silicon nitride film 8 is overetched in the dry etching thereof, the aluminum oxide film 7 functions as an etching stopper. Therefore, it is possible to prevent the semiconductor substrate 1 made of silicon from being etched (recessed). Accordingly, a problem caused by etching the semiconductor substrate 1 can be solved.

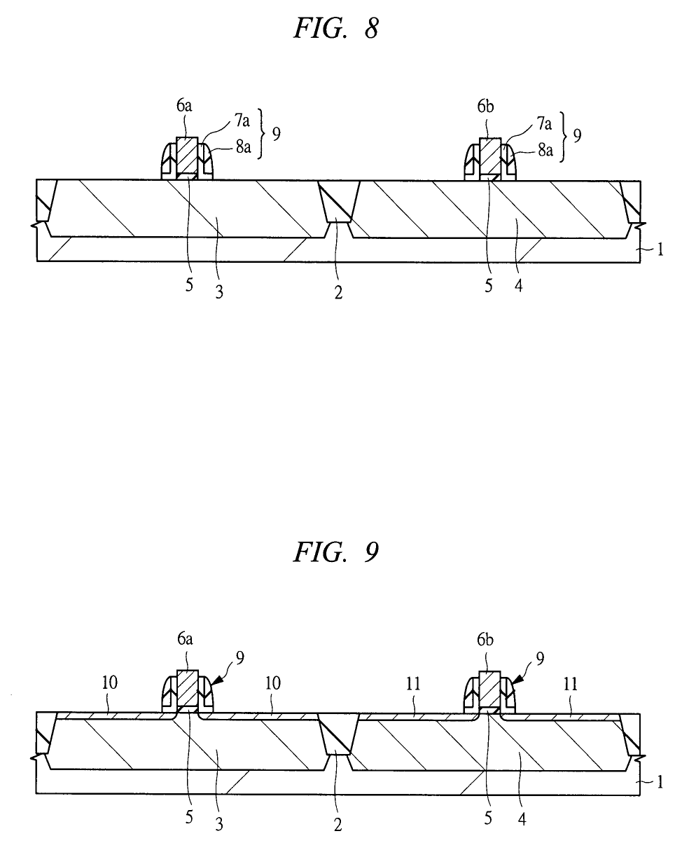

Next, as shown in FIG. 8, the aluminum oxide film 7 exposed by removing the silicon nitride film 8 is removed. The exposed aluminum oxide film 7 can be removed by wet etching using, for example, a diluted hydrofluoric acid. Although the exposed aluminum oxide film 7 is removed by the wet etching using the diluted hydrofluoric acid, the semiconductor substrate 1 under the aluminum oxide film 7 is not etched. The diluted hydrofluoric acid can easily remove the aluminum oxide film 7 but cannot etch silicon. Therefore, the semiconductor substrate 1 is not etched in the step of removing the aluminum oxide film 7.

In the wet etching using diluted hydrofluoric acid, the silicon nitride films 8a are not removed. Therefore, the silicon nitride films 8a formed on the sidewalls of the silicon gate electrodes 6a and 6b are left as they are. Accordingly, aluminum oxide films 7a covered with the silicon nitride films 8a are left on the sidewalls of the silicon gate electrodes 6a and 6b. In this manner, the first laminated films 9 formed of the aluminum oxide films 7a and the silicon nitride films 8a are formed on the sidewalls of the silicon gate electrodes 6a and 6b. In the first laminated film 9, the aluminum oxide film 7a is formed as a lower layer, and the silicon nitride film 8a is formed on the aluminum oxide film 7a. The aluminum oxide films 7a are formed to have an L-shape along the sidewalls of the silicon gate electrodes 6a and 6b. Since the aluminum oxide film 7a is formed to have an L-shape, a part of the aluminum oxide film 7a is in contact with the semiconductor substrate 1. Meanwhile, since the silicon nitride films 8a are formed on the aluminum oxide films 7a, the silicon nitride films 8a are not in direct contact with the semiconductor substrate 1.

In the first laminated film 9, since sufficient overetching is performed when the silicon nitride films 8a is formed, the bottom end of the silicon nitride films 8a can be patterned appropriately. Therefore, the first laminated film 9 can be formed to have an accurate width, and a width approximate to a design value can be realized. On the other hand, even though the silicon nitride film 8 is overetched, the semiconductor substrate 1 made of silicon can be prevented from being etched because the aluminum oxide film 7 is formed under the silicon nitride film 8. As described above, according to the first embodiment, the first laminated films 9 whose widths are controlled with high accuracy can be formed on the sidewalls of the silicon gate electrodes 6a and 6b. At the same time, even though the first laminated film 9 having an accurate width is formed, the semiconductor substrate 1 can be prevented from being etched.

Incidentally, Patent Document 1 discloses a technology in which a first sidewall formed of an aluminum oxide film is formed on a sidewall of a gate electrode and a second sidewall formed of a silicon nitride film outside the first sidewall. However, in the technology described in Patent Document 1, both the first sidewall formed of the aluminum oxide film and the second sidewall formed of the silicon nitride film are in contact with the semiconductor substrate.

The structure of the sidewall described in Patent Document 1 and the structure of the first laminated film 9 in the first embodiment are in common in that each of the sidewall and the first laminated film 9 is formed of a laminated film of an aluminum oxide film and a silicon nitride film. However, both the first and second sidewalls are in contact with the semiconductor substrate in the structure of the sidewall described in Patent Document 1. More specifically, both the aluminum oxide film and the silicon nitride film are in contact with the semiconductor substrate. Meanwhile, in the first laminated film 9 according to the first embodiment, the aluminum oxide film 7a is in contact with the semiconductor substrate 1, but the silicon nitride film 8a is not in contact with the semiconductor substrate 1. In this respect, the technology described in the first embodiment is different from the technology described in Patent Document 1.

For example, the structure in which both the aluminum oxide film and the silicon nitride film are in contact with the semiconductor substrate can be formed in the following manner. For example, after an aluminum oxide film is formed on a semiconductor substrate including gate electrodes, the aluminum oxide film is removed by anisotropic dry etching so that the aluminum oxide film is formed only on sidewalls of a gate electrode. Subsequently, a silicon nitride film is formed on the semiconductor substrate including the gate electrode having the aluminum oxide films left on the sidewalls thereof. Then, anisotropic dry etching is performed to the silicon nitride film so that a second sidewall formed of a silicon nitride film is formed outside the first sidewall formed of an aluminum oxide film. In this manner, the sidewall structure described in Patent Document 1 can be formed. In the manufacturing method as described above, when the aluminum oxide film is dry-etched and the silicon nitride film is dry-etched, the semiconductor substrate is etched.

Meanwhile, in the step of forming the first laminated film 9 in the first embodiment, the aluminum oxide film 7 and the silicon nitride film 8 are laminated on the semiconductor substrate 1 including the silicon gate electrodes 6a and 6b. Further, by performing the anisotropic dry etching of the silicon nitride film 8, the silicon nitride films 8a are left only on the sidewalls of the silicon gate electrodes 6a and 6b and the silicon nitride film 8 in the other regions is removed. At this time, since the aluminum oxide film 7 formed under the silicon nitride film 8 functions as an etching stopper, the semiconductor substrate 1 is not etched. Thereafter, the exposed aluminum oxide film 7 is removed by wet etching using diluted hydrofluoric acid. At this time, the semiconductor substrate 1 is not etched by the wet etching using diluted hydrofluoric acid. The first embodiment is characterized in that the aluminum oxide film 7 functions as an etching stopper in the step of removing the silicon nitride film 8 in the manufacturing process, and in this structure, the semiconductor substrate 1 can be prevented from being etched. According to the manufacturing process described above, the aluminum oxide film 7a is inevitably in contact with the semiconductor substrate 1 and the silicon nitride films 8a is not in direct contact with the semiconductor substrate 1.

As described above, in the structure of the sidewall described in Patent Document 1, the semiconductor substrate is etched. On the other hand, in the structure of the first laminated film 9 described in the first embodiment, a remarkable advantage can be achieved, that is, it is possible to form the first laminated film 9 with an accurate width, and at the same time, it is possible to prevent the semiconductor substrate from being etched.

The aluminum oxide film 7a has characteristics that oxygen and nitrogen hardly penetrate through it. For this reason, by forming the aluminum oxide films 7a on the sidewalls of the silicon gate electrodes 6a and 6b, it is possible to prevent silicon oxide films from being formed on the upper and lower interfaces of the high dielectric constant film constituting the gate insulating film 5. The formation of the silicon oxide films on the upper and lower interfaces of the high dielectric constant film is observed particularly when the gate lengths of the silicon gate electrodes 6a and 6b are 20 nm or less, further, 10 nm or less. Therefore, a remarkable advantage can be achieved when the structure of the present invention is applied to the silicon gate electrodes 6a and 6b having gate lengths of 20 nm or less, desirably, 10 nm or less. From this standpoint, it seems that the sidewalls formed of only the aluminum oxide films 7a may be formed on the sidewalls of the silicon gate electrodes 6a and 6b. However, it is difficult to prevent the semiconductor substrate 1 from being etched in this structure. More specifically, when the sidewalls formed of the aluminum oxide films 7a are formed on the sidewalls of the silicon gate electrodes 6a and 6b, the aluminum oxide film 7 is formed on the semiconductor substrate 1 including the silicon gate electrodes 6a and 6b, and the aluminum oxide film 7 is anisotropically dry-etched. In this manner, the aluminum oxide films 7a can be formed only on the sidewalls of the silicon gate electrodes 6a and 6b. However, the aluminum oxide film 7 is not easily dry-etched, and the silicon of the semiconductor substrate 1 is also etched under the condition in which the aluminum oxide film 7 can be dry-etched. Therefore, the semiconductor substrate 1 is etched. On the other hand, when the aluminum oxide film 7 is to be removed by wet etching, the aluminum oxide films 7a on the sidewalls of the silicon gate electrodes 6a and 6b are removed because the wet etching is isotropic etching. Accordingly, it can be understood that the structure where the sidewalls formed of only the aluminum oxide films 7a are formed on the sidewalls of the silicon gate electrodes 6a and 6b is difficult to be used from the standpoint of preventing the semiconductor substrate 1 from being etched.

It can be understood from the above that, from the standpoint of preventing the silicon oxide films from being formed on the upper and lower interfaces of the high dielectric constant film constituting gate insulating film 5 and preventing the semiconductor substrate 1 from being etched, it is necessary to form the first laminated films 9 each obtained by laminating the aluminum oxide film 7a and the silicon nitride film 8a on the sidewalls of the silicon gate electrodes 6a and 6b. One important feature of the present invention is that the aluminum oxide film 7 is selected as one of the films constituting the first laminated film 9. More specifically, in order to achieve both an object to prevent the silicon oxide films from being formed on the upper and lower interfaces of the high dielectric constant film and an object to prevent the semiconductor substrate 1 from being etched, the film having the characteristics that oxygen and nitrogen hardly penetrate through it and exhibiting high resistance to dry etching must be used. Further, the film must be easily removed by wet etching. The present invention can be devised for the first time when the aluminum oxide film 7 is found as a material having these characteristics.

Next, as shown in FIG. 9, by using a photolithography technology and an ion implantation method, the shallow n type impurity diffusion region 10 is formed in alignment with the first laminated film 9 formed on the sidewall of the silicon gate electrode 6a. The shallow n type impurity diffusion region 10 can be formed by implanting, for example, an n type impurity such as phosphorous or arsenic into the semiconductor substrate 1.

Since the shallow n type impurity diffusion region 10 is formed in alignment with the width of the first laminated film 9 formed with high accuracy, the shallow n type impurity diffusion region 10 can be formed as designed. More specifically, according to the first embodiment, the shallow n type impurity diffusion region 10 constituting a part of the source region and the drain region can be formed as designed, and the variation in electric characteristics due to the positional shift of the shallow n type impurity diffusion region 10 in each of the semiconductor devices can be suppressed.

Similarly, by using a photolithography technology and an ion implantation method, the shallow p type impurity diffusion region 11 is formed in alignment with the first laminated film 9 formed on the sidewall of the silicon gate electrode 6b. The shallow p type impurity diffusion region 11 can be formed by implanting a p type impurity such as boron into the semiconductor substrate 1.

Since the shallow p type impurity diffusion region 11 is formed in alignment with the width of the first laminated film 9 formed with high accuracy, the shallow p type impurity diffusion region 11 can be formed as designed.

In the first embodiment, as shown in FIG. 8, after the first laminated film 9 is formed, the shallow n type impurity diffusion region 10 and the shallow p type impurity diffusion region 11 are formed. However, as shown in FIG. 7, it is also possible to form the shallow n type impurity diffusion region 10 and the shallow p type impurity diffusion region 11 before the aluminum oxide film 7 is removed. More specifically, the impurity can be implanted into the semiconductor substrate 1 through the aluminum oxide film 7.

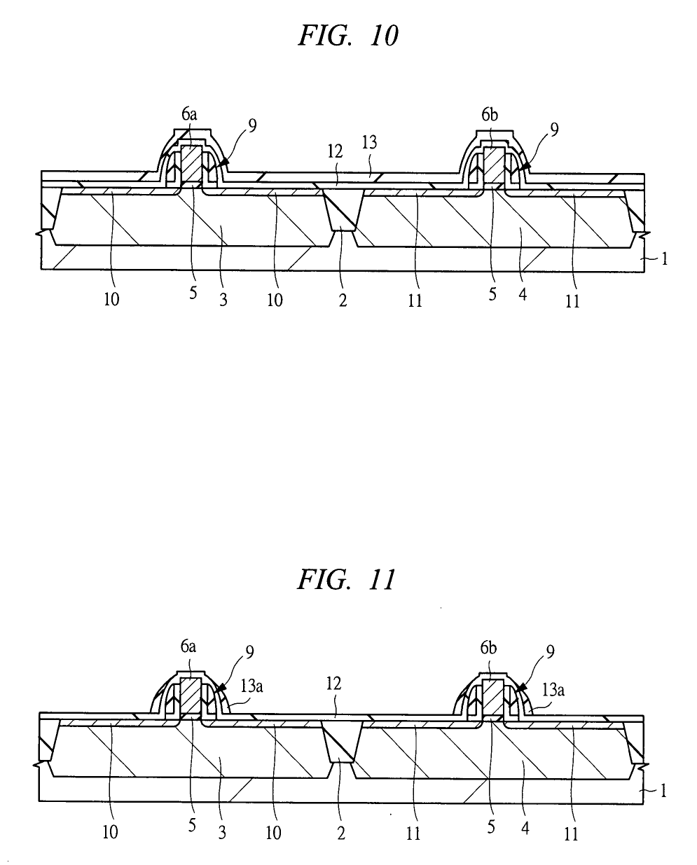

Subsequently, as shown in FIG. 10, the aluminum oxide film 12 and the silicon nitride film 13 are formed on the semiconductor substrate 1. The aluminum oxide film 12 can be formed by, for example, an ALD method, and the silicon nitride film 13 can be formed by using, for example, a CVD method.

Then, as shown in FIG. 11, the silicon nitride film 13 is removed by anisotropic dry etching. In this manner, a silicon nitride film 13a can be left outside the first laminated film 9, and the silicon nitride film 13 formed in the other regions can be removed. In this case, the aluminum oxide film 12 is formed under the silicon nitride film 13, and the aluminum oxide film 12 functions as an etching stopper. Therefore, the semiconductor substrate 1 under the aluminum oxide film 12 is protected, which makes it possible to prevent the semiconductor substrate 1 from being etched. Also, since the silicon nitride film 13 is sufficiently removed by overetching, the bottom end of the silicon nitride film 13a formed outside the first laminated film 9 can be patterned appropriately, and a designed width can be realized with high accuracy.

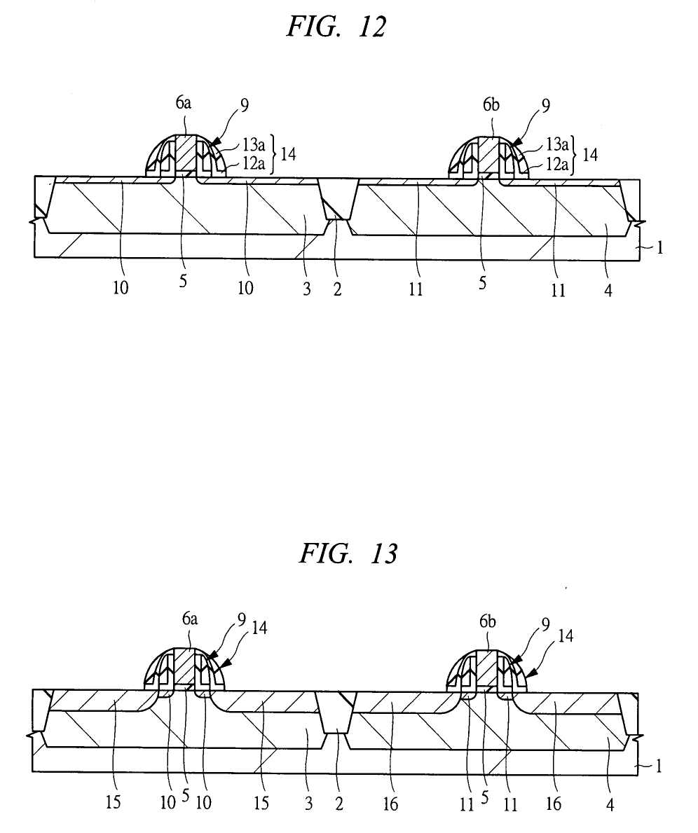

Next, as shown in FIG. 12, the aluminum oxide film 12 is removed by wet etching using, for example, diluted hydrofluoric acid. By doing so, the exposed aluminum oxide film 12 is removed, and only an aluminum oxide film 12a covered with the silicon nitride film 13a is left. In this manner, the second laminated film 14 formed of the aluminum oxide film 12a and the silicon nitride film 13a can be formed outside the first laminated film 9.

Subsequently, as shown in FIG. 13, by using a photolithography technology and an ion implantation method, the deep n type impurity diffusion region 15 is formed in alignment with the second laminated film 14 formed on the silicon gate electrode 6a. The deep n type impurity diffusion region 15 can be formed by implanting an n type impurity such as phosphorous or arsenic into the semiconductor substrate 1. Since the deep n type impurity diffusion region 15 is also formed in alignment with the second laminated film 14 controlled with high accuracy, the deep n type impurity diffusion region 15 can be formed at a designed position.

Similarly, the deep p type impurity diffusion region 16 is formed in alignment with the second laminated film 14 formed on the silicon gate electrode 6b. The deep p type impurity diffusion region 16 can be formed by implanting a p type impurity such as boron into the semiconductor substrate 1. Since the deep p type impurity diffusion region 16 is also formed in alignment with the second laminated film 14 controlled with high accuracy, the deep p type impurity diffusion region 16 can be formed at a designed position.

In this manner, in the n channel MISFET, the source region and the drain region are formed from the shallow n type impurity diffusion region 10 and the deep n type impurity diffusion region 15. Also, in the p channel MISFET, the source region and the drain region are formed from the shallow p type impurity diffusion region 11 and the deep p type impurity diffusion region 16.

Thereafter, in order to activate the impurity implanted in the source region or the drain region, heat treatment is performed to the semiconductor substrate 1. At this time, since the semiconductor substrate 1 is not etched in the first embodiment, a sufficient crystal region in which no impurity is implanted is present in the semiconductor substrate 1. Therefore, the crystal defect formed due to the impurity implantation can be sufficiently recovered on the basis of the crystal region.

Further, even though the heat treatment is performed to activate the impurity, since the aluminum oxide film 7a is formed so as to cover the sidewall of the gate insulating film 5, the penetration of oxygen or nitrogen into the gate insulating film 5 can be prevented by the aluminum oxide film 7a. Therefore, it is possible to prevent silicon oxide films from being formed on the upper and lower interfaces of the gate insulating film 5.

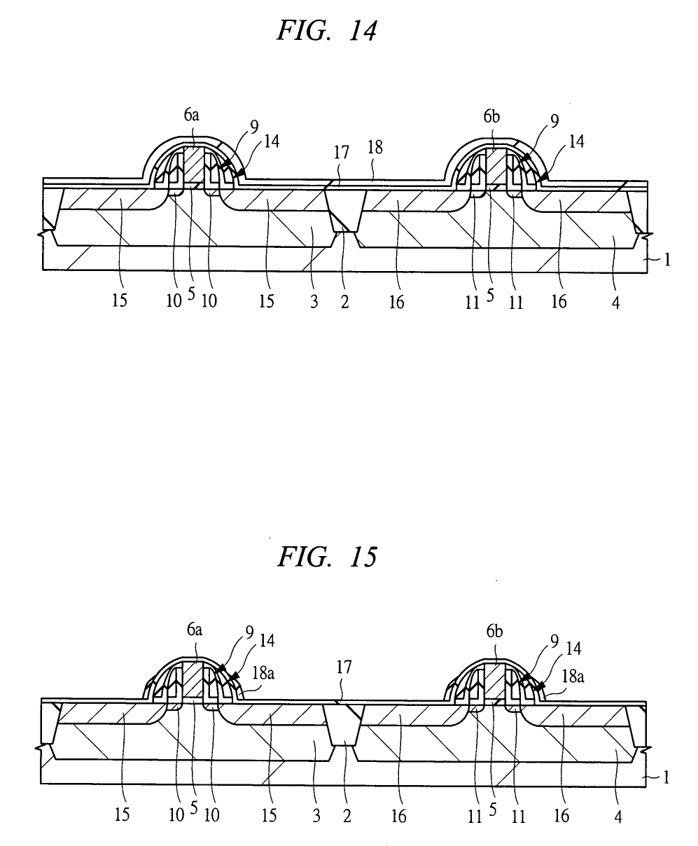

Next, as shown in FIG. 14, an aluminum oxide film 17 and a silicon nitride film 18 are formed on the semiconductor substrate 1. The aluminum oxide film 17 can be formed by using, for example, an ALD method, and the silicon nitride film 18 can be formed by using, for example, a CVD method.

Then, as shown in FIG. 15, the silicon nitride film 18 is removed by anisotropic dry etching. By doing so, a silicon nitride film 18a can be left outside the second laminated film 14, and the silicon nitride film 18 formed in the other regions can be removed. In this case, the aluminum oxide film 17 is formed under the silicon nitride film 18, and the aluminum oxide film 17 functions as an etching stopper. For this reason, the semiconductor substrate 1 under the aluminum oxide film 17 is protected, which makes it possible to prevent the semiconductor substrate 1 from being etched. Also, since the silicon nitride film 18 is sufficiently removed by overetching, the bottom end of the silicon nitride film 18a formed outside the second laminated film 14 can be patterned appropriately, and a designed width can be realized with high accuracy.

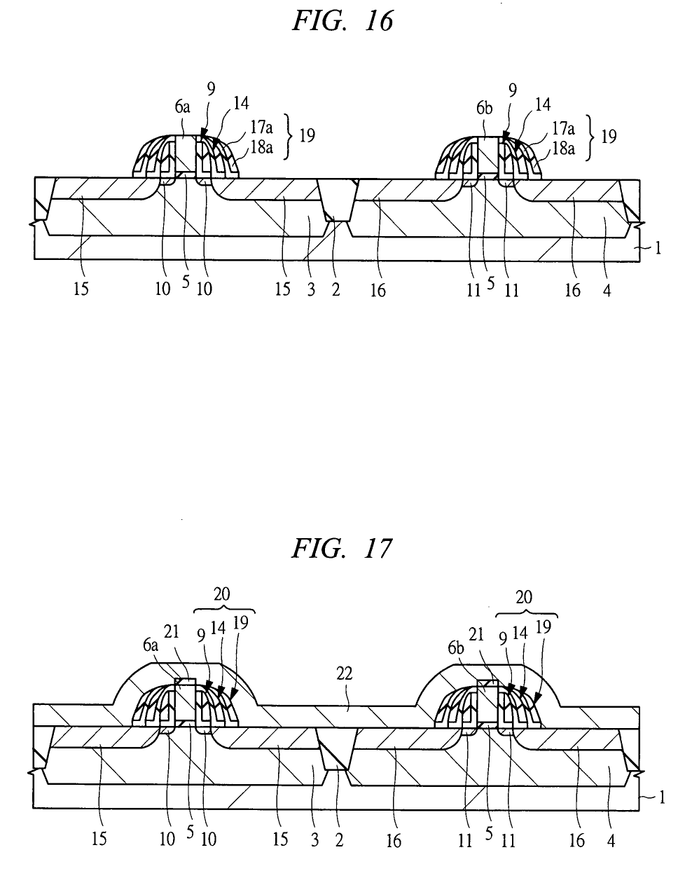

Next, as shown in FIG. 16, the aluminum oxide film 17 is removed by wet etching using, for example, diluted hydrofluoric acid. By doing so, the exposed aluminum oxide film 17 is removed, and only an aluminum oxide film 17a covered with the silicon nitride film 18a is left. In this manner, the third laminated film 19 formed of the aluminum oxide film 17a and the silicon nitride film 18a can be formed outside the second laminated film 14. In the manner as described above, the sidewall 20 formed of the first laminated film 9, the second laminated film 14, and the third laminated film 19 can be formed on each of the sidewalls of the silicon gate electrodes 6a and 6b.

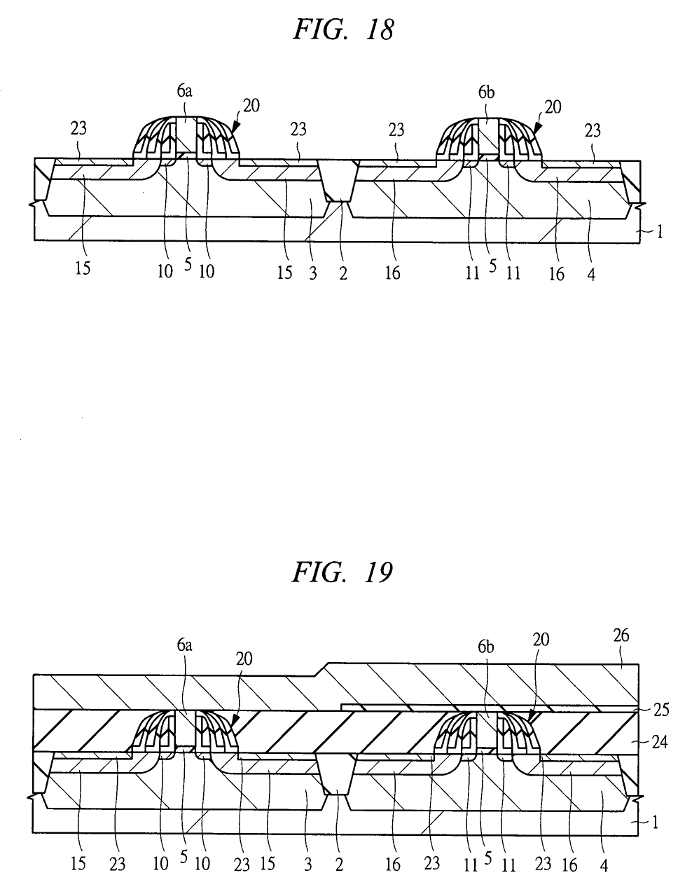

Subsequently, as shown in FIG. 17, after an insulating film 21 is formed on the semiconductor substrate 1, the insulating film 21 is patterned so as to cover the silicon gate electrodes 6a and 6b by using a photolithography technology and an etching technology. Then, a nickel film 22 is formed on the semiconductor substrate 1. The nickel film 22 can be formed by using, for example a sputtering method. Thereafter, by performing heat treatment, the nickel film 22 is reacted with silicon, thereby forming the nickel silicide films 23 in the deep n type impurity diffusion region 15 and the deep p type impurity diffusion region 16 as shown in FIG. 18. The nickel silicide film 23 is formed in alignment with the sidewall 20.

The nickel silicide films (metal silicide films) 23 are formed to reduce the resistance of the deep n type impurity diffusion region 15 and the deep p type impurity diffusion region 16. In place of the nickel silicide film, a cobalt silicide film or a titanium silicide film may be formed.

In the case where the silicon gate electrodes 6a and 6b are formed of polysilicon films, an n channel MISFET and a p channel MISFET can be formed in the process described above. When the silicon gate electrodes 6a and 6b are used, although not described in the first embodiment, an n type impurity may be implanted into the silicon gate electrode 6a of the n channel MISFET, and a p type impurity may be implanted into the silicon gate electrode 6b of the p channel MISFET. By this means, in the n channel MISFET, a work function value of the silicon gate electrode 6a can be approximated to the conduction band of silicon. On the other hand, in the p channel MISFET, a work function value of the silicon gate electrode 6b can be approximated to the valence band of silicon. For this reason, it is possible to reduce the threshold voltage in both the MISFETs.

Further, when the silicon gate electrodes 6a and 6b are used, it is also possible to form metal silicide films on the silicon gate electrodes 6a and 6b. In this structure, the resistance of the silicon gate electrodes 6a and 6b can be reduced. More specifically, in FIG. 17, if the nickel films 22 are formed to be in direct contact with the silicon gate electrodes 6a and 6b without forming the insulating films 21 on the silicon gate electrodes 6a and 6b, respectively, nickel silicide films can be formed on the silicon gate electrodes 6a and 6b by the subsequent heat treatment.

Also, even if a metal film is used as a gate electrode, the same process as described above is performed except that metal films are used in place of the silicon gate electrodes 6a and 6b.

A manufacturing process in the case where a metal silicide film is used as a gate electrode will be described below. After the process shown in FIG. 18, an insulating film 24 is formed on the semiconductor substrate 1 so as to cover the silicon gate electrodes 6a and 6b as shown in FIG. 19. Then, the surface of the insulating film 24 is polished by a chemical mechanical polishing method (CMP method) to expose the surfaces of the silicon gate electrodes 6a and 6b. Subsequently, after an insulating film 25 is formed on the insulating film 24, the insulating film 25 is patterned by using a photolithography technology and an etching technology. The insulating film 25 is patterned so that the insulating film 25 is left in the p channel MISFET forming region.

Subsequently, a nickel film 26 is formed on the semiconductor substrate 1. The nickel film 26 is formed by using, for example, a sputtering method. At this time, the nickel film 26 is in direct contact with the silicon gate electrode 6a. On the other hand, since the insulating film 25 is formed on the silicon gate electrode 6b, the silicon gate electrode 6b and the nickel film 26 are not in direct contact with each other. The nickel film 26 is designed to have a sufficient thickness so that the silicon gate electrode 6a can be completely silicided.

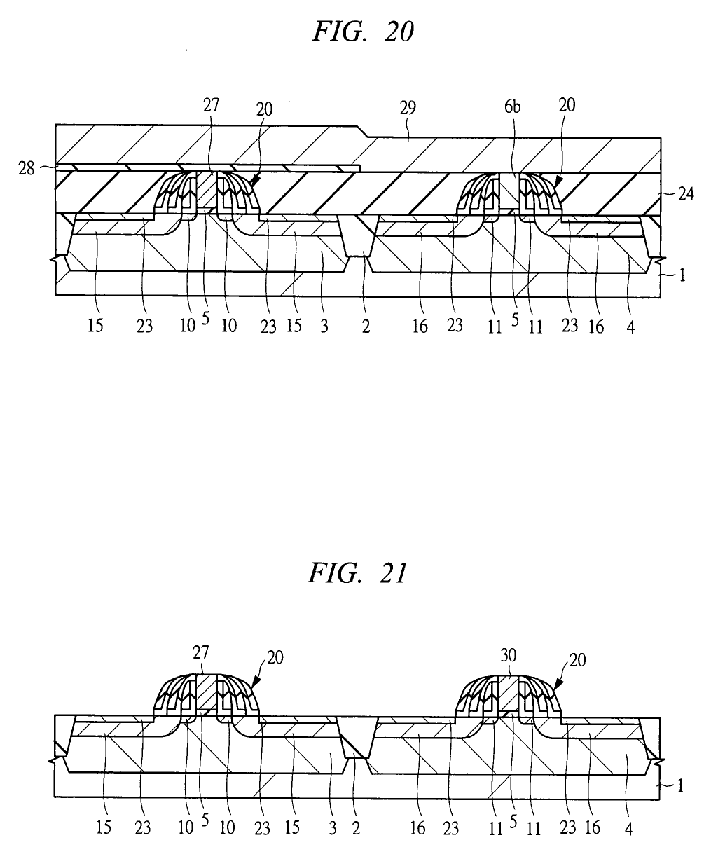

Next, by performing the heat treatment, the silicon gate electrode 6a is reacted with the nickel film 26 to form the gate electrode (full silicide electrode) 27 formed of the nickel silicide film (see FIG. 20). Thereafter, after an unreacted nickel film 26 and the insulating film 25 are removed, as shown in FIG. 20, an insulating film 28 is formed. The insulating film 28 is patterned so as to be left only in the n channel MISFET forming region. Then, a platinum film 29 is formed on the semiconductor substrate 1. The platinum film 29 can be formed by using, for example, a CVD method. At this time, the platinum film 29 is in direct contact with the silicon gate electrode 6b. On the other hand, since the insulating film 28 is formed on the silicon gate electrode 6a, the silicon gate electrode 6a and the platinum film 29 are not in direct contact with each other. The platinum film 29 is designed to have a sufficient thickness so that the silicon gate electrode 6b can be completely silicided.

Subsequently, by performing the heat treatment, the silicon gate electrode 6b is reacted with the platinum film 29 to form the gate electrode (full silicide electrode) 30 formed of a platinum silicide film. Thereafter, an unreacted platinum film 29, the insulating film 28, and the insulating film 24 are removed. By this means, an n channel MISFET and a p channel MISFET can be formed as shown in FIG. 21. Also, in FIG. 20, the insulating film 24 can be used as an interlayer insulating film without removing it.

According to the first embodiment, the gate electrode 27 of the n channel MISFET is formed of a nickel silicide film, and the gate electrode 30 of the p channel MISFET is formed of a platinum silicide film. A work function value of the nickel silicide film is a value approximate to the conduction band of silicon, and a work function value of the platinum silicide film is a value approximate to the valence band of silicon. Therefore, threshold values in the n channel MISFET and the p channel MISFET can be reduced.

Further, in the first embodiment, the step of forming the nickel silicide films 23 on the deep n type impurity diffusion region 15 and the deep p type impurity diffusion region 16 and the step of forming the gate electrode 27 formed of the nickel silicide film are performed separately. This is because of a difference in thickness between the nickel film 22 formed on the deep n type impurity diffusion region 15 and the deep p type impurity diffusion region 16 and the nickel film 26 formed on the silicon gate electrode 6a. More specifically, it is sufficient if the nickel silicide films 23 to be formed on the deep n type impurity diffusion region 15 and the deep p type impurity diffusion region 16 are formed only in the surface areas of the deep n type impurity diffusion region 15 and the deep p type impurity diffusion region 16. On the other hand, the nickel silicide film formed on the silicon gate electrode 6a is required to have a thickness sufficient to completely silicide the silicon gate electrode 6a. For this reason, in general, the film thickness of the nickel films 22 formed on the deep n type impurity diffusion region 15 and the deep p type impurity diffusion region 16 is relatively small, and that of the nickel film 26 formed on the silicon gate electrode 6a is relatively large. Therefore, these steps are performed separately. However, along with the miniaturization of the silicon gate electrode 6a, if the nickel film 26 formed on the silicon gate electrode 6a can have the thickness almost equal to the film thickness of each of the nickel films 22 formed on the deep n type impurity diffusion region 15 and the deep p type impurity diffusion region 16, the step of forming the nickel silicide films 23 on the deep n type impurity diffusion region 15 and the deep p type impurity diffusion region 16 and the step of forming the nickel silicide film on the silicon gate electrode 6a can be performed as one step.

In this manner, the n channel MISFET and the p channel MISFET can be formed. Next, a wiring step will be described below. As shown in FIG. 1, the silicon nitride film 31 and the silicon oxide film 32 are formed on the main surface of the semiconductor substrate 1. The silicon nitride film 31 and the silicon oxide film 32 constitute an interlayer insulating film. The silicon nitride film 31 and the silicon oxide film 32 can be formed by using, for example, a CVD method. Thereafter, the surface of the silicon oxide film 32 is planarized by using, for example, a CMP (Chemical Mechanical Polishing) method.

Next, the contact holes 33 are formed in the interlayer insulating film by using a photolithography technology and an etching technology. Subsequently, a titanium/titanium nitride film is formed on the silicon oxide film 32 including a bottom surface and an inner wall of the contact holes 33. The titanium/titanium nitride film is formed of a laminated film of a titanium film and a titanium nitride film, and it can be formed by using, for example, a sputtering method. The titanium/titanium nitride film has a so-called barrier property for preventing tungsten which is a material of a film to be buried in a subsequent step from being diffused into silicon.

Subsequently, a tungsten film is formed on an entire main surface of the semiconductor substrate 1 so as to fill the contact holes 33. The tungsten film can be formed by using, for example, a CVD method. Then, an unnecessary titanium/titanium nitride film and an unnecessary tungsten film formed on the silicon oxide film 32 are removed by, for example, a CMP method, thereby forming the plugs 34.

Next, a titanium/titanium nitride film, an aluminum film, and a titanium/titanium nitride film are sequentially formed on the silicon oxide film 32 and the plugs 34. These films can be formed by using, for example a sputtering method. Subsequently, these films are patterned by using a photolithography technology and an etching technology to form the wirings 35. Further, although wirings are formed on the wirings 35, the description thereof is omitted here. In this manner, the semiconductor device according to the first embodiment can be formed.

Although the first embodiment describes the example in which the aluminum wirings are formed, for example, copper wirings can be formed by a Damascene method.

Further, in the first embodiment, the sidewall 20 is formed of the first laminated film 9, the second laminated film 14, and the third laminated film 19. However, it is not meant to be restrictive. For example, the sidewall 20 may be formed of the first laminated film 9 and the second laminated film 14 or may be formed of only the first laminated film 9.

### Second Embodiment

In the second embodiment, an example in which an n channel MISFET and a p channel MISFET are formed on an SOI substrate will be described with reference to the accompanying drawings.

First, the SOI substrate is prepared. The SOI substrate is a substrate having single crystal silicon formed on an insulator. For example, an SOI substrate called a SIMOX (Silicon Implanted Oxide) and an SOI substrate called a bonded substrate are known. In the SOI substrate called a SIMOX, after oxygen is ion-implanted into a semiconductor substrate made of silicon at a high energy (up to 180 Kev) and at a high concentration, high-temperature heat treatment is performed to form a buried oxide film in the semiconductor substrate. In the SOI substrate called a bonded substrate, after a semiconductor substrate made of silicon having a silicon oxide film formed thereon is thermally bonded to another substrate made of silicon via the silicon oxide film, a single crystal silicon layer is provided on the silicon oxide film obtained by polishing and removing one of the substrates halfway. When a MISFET is formed on the SOI substrate, the complete element isolation can be realized. Further, since the capacitance of the source region or the drain region can be reduced, integration density and operation speed can be improved, and latch-up free can be realized.

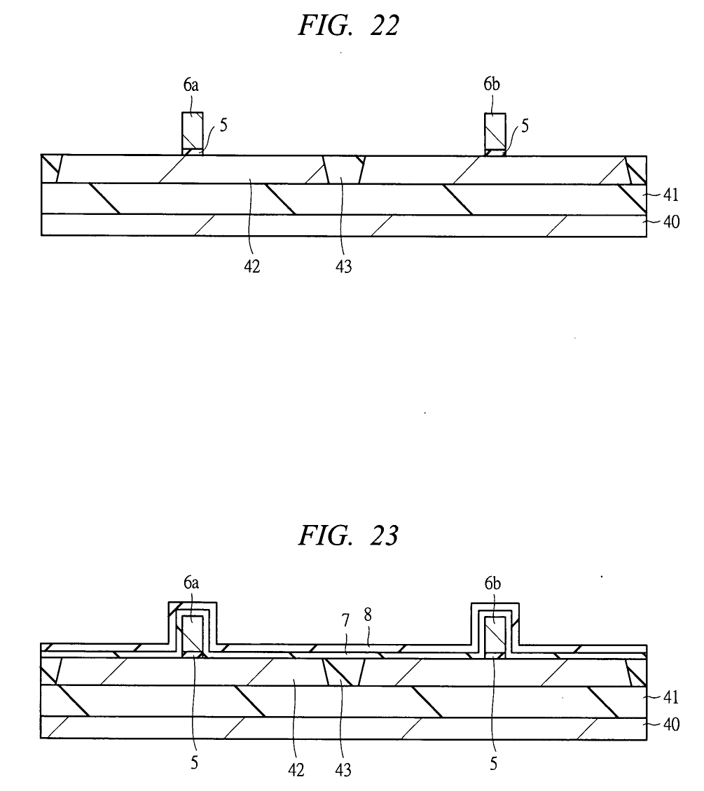

Next, a manufacturing method of a CMISFET according to the second embodiment using an SOI substrate will be described below. FIG. 22 shows an example of an SOI substrate. As shown in FIG. 22, for example, a buried oxide film 41 formed of a silicon oxide film is formed in a semiconductor substrate 40 made of single crystal silicon. A single crystal silicon layer 42 is formed on the buried oxide film 41. The film thickness of the single crystal silicon layer 42 is adjusted to, for example, about 10 nm by adjusting the thickness of the SOI substrate through the oxidation process and the process using diluted hydrofluoric acid to the substrate before the element isolation step. The SOI substrate as described above is formed of, for example, an SIMOX substrate, a bonded substrate, or the like.

Subsequently, an element isolation region 43 is formed in the single crystal silicon layer 42. The element isolation region 43 is formed by using, for example, an STI method. The element isolation region 43 reaches the buried oxide film 41 formed under the single crystal silicon layer 42. Therefore, active regions can be completely isolated by the element isolation region 43.

Thereafter, a gate insulating film 5 formed of, for example, a high dielectric constant film is formed on the single crystal silicon layer 42, and a polysilicon film is formed on the gate insulating film 5. The high dielectric constant film constituting the gate insulating film 5 can be formed by, for example, an ALD method or a CVD method, and the polysilicon film can be formed by, for example, a CVD method.

Then, the polysilicon film is patterned by using a photolithography technology and an etching technology to form silicon gate electrodes 6a and 6b.

Next, as shown in FIG. 23, a laminated film of an aluminum oxide film 7 and a silicon nitride film 8 is formed on the single crystal silicon layer 42 including the silicon gate electrodes 6a and 6b. The aluminum oxide film 7 can be formed by using, for example, an ALD method, and the silicon nitride film 8 can be formed by, for example, a CVD method. Since the aluminum oxide film 7 can be formed at a relatively low temperature ranging from 100° C. to 500° C., typically, 200° C. to 300° C., it is possible to prevent silicon oxide films from being formed on the upper and lower interfaces of the high dielectric constant film constituting the gate insulating film 5 in the step of forming the aluminum oxide film 7. Further, since the aluminum oxide film 7 has characteristics that oxygen and nitrogen hardly penetrate through it, the supply of oxygen to the high dielectric constant film can be suppressed in the step of forming the silicon nitride film 8 on the aluminum oxide film 7. For this reason, in the step of forming the silicon nitride film 8, the increase in the film thickness of the gate insulating film 5 can be prevented.

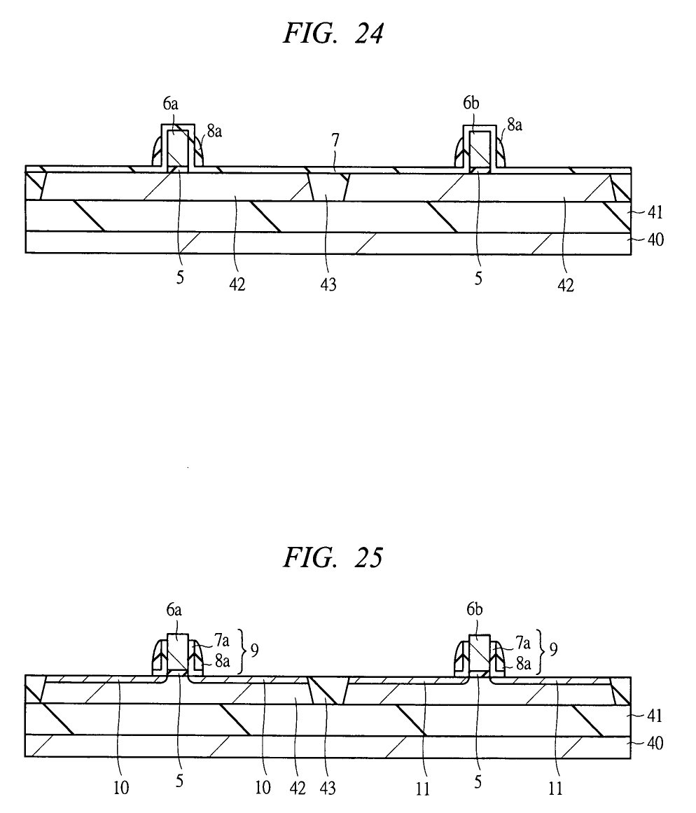

Subsequently, as shown in FIG. 24, the silicon nitride film 8 is removed by anisotropic dry etching. By doing so, silicon nitride films 8a are left only on the sidewalls of the silicon gate electrodes 6a and 6b, and the silicon nitride film 8 in the other regions are removed. In this case, since the aluminum oxide film 7 is formed under the silicon nitride film 8, the aluminum oxide film 7 functions as an etching stopper. Therefore, the single crystal silicon layer 42 formed under the aluminum oxide film 7 can be protected, and the single crystal silicon layer 42 can be prevented from being etched. Since the film thickness of the single crystal silicon layer 42 is very small in the SOI substrate, when the single crystal silicon layer 42 is etched, the film thicknesses of the source region and the drain region decrease, and the resistances thereof are apt to increase. Furthermore, when the amount of etching is large, it becomes difficult to form the source or the drain region. However, in the second embodiment, since the aluminum oxide film 7 functions as an etching stopper, it is possible to prevent the very thin single crystal silicon layer 42 from being etched. The effect obtained by forming the aluminum oxide film 7 conspicuously appears on the SOI substrate.

Also, since the aluminum oxide film 7 functions as an etching stopper, the silicon nitride film 8 can be sufficiently overetched in the anisotropic dry etching thereof. Accordingly, the bottom ends of the silicon nitride films 8a formed on the sidewalls of the silicon gate electrodes 6a and 6b can be patterned appropriately, and the widths of the silicon nitride films 8a can be approximated to a design value with high accuracy.

Next, as shown in FIG. 25, the aluminum oxide film 7 exposed by removing the silicon nitride film 8 is removed by wet etching using diluted hydrofluoric acid. By this means, first laminated films 9 whose widths are adjusted with high accuracy can be formed on the sidewalls of the silicon gate electrodes 6a and 6b. The first laminated film 9 is formed of a laminated film of an aluminum oxide film 7a and the silicon nitride film 8a. Thereafter, a shallow n type impurity diffusion region 10 and a shallow p type impurity diffusion region 11 are formed in alignment with the first laminated film 9. Since the shallow n type impurity diffusion region 10 and the shallow p type impurity diffusion region 11 are formed in alignment with the first laminated film 9 controlled with high accuracy, forming positions of the shallow n type impurity diffusion region 10 and the shallow p type impurity diffusion region 11 are controlled with high accuracy.

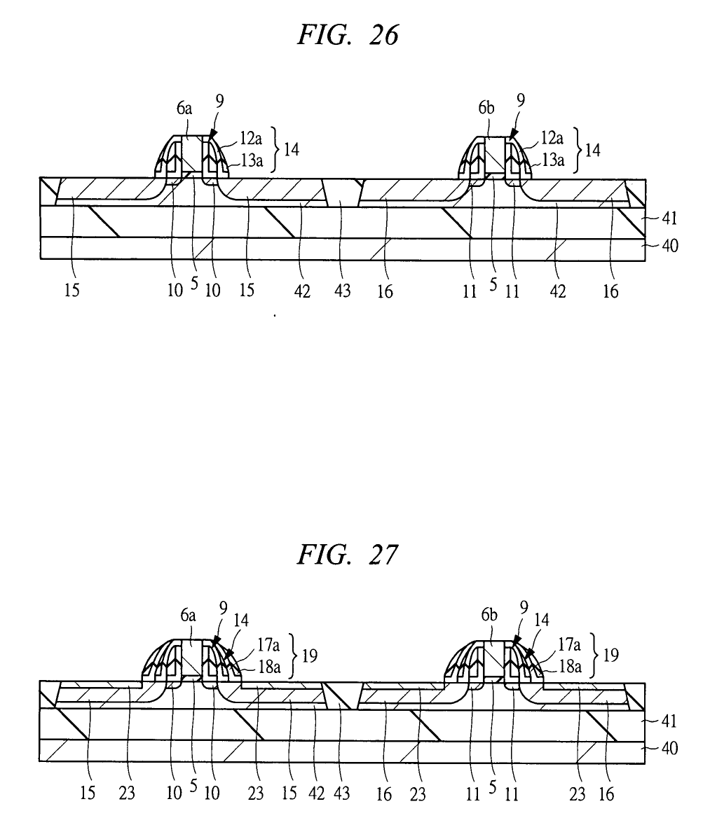

Subsequently, as shown in FIG. 26, by using the same method as that for forming the first laminated film 9, a second laminated film 14 is formed outside the first laminated film 9. The second laminated film 14 is formed of an aluminum oxide film 12a and a silicon nitride film 13a. The width of the second laminated film 14 is also adjusted with high accuracy, and the single crystal silicon layer 42 can be prevented from being etched in the step of forming the second laminated film 14. Thereafter, a deep n type impurity diffusion region 15 and a deep p type impurity diffusion region 16 are formed in alignment with the second laminated film 14. Since the forming positions of the deep n type impurity diffusion region 15 and the deep p type impurity diffusion region 16 can be also controlled with high accuracy, the variation in element characteristics in a plurality of semiconductor devices can be suppressed.

Next, as shown in FIG. 27, by using the same method as that for forming the first laminated film 9 and the second laminated film 14, a third laminated film 19 is formed outside the second laminated film 14. The third laminated film 19 is formed of an aluminum oxide film 17a and a silicon nitride film 18a. Thereafter, nickel silicide films 23 are formed on the surfaces of the deep n type impurity diffusion region 15 and the deep p type impurity diffusion region 16 formed outside the third laminated film 19.

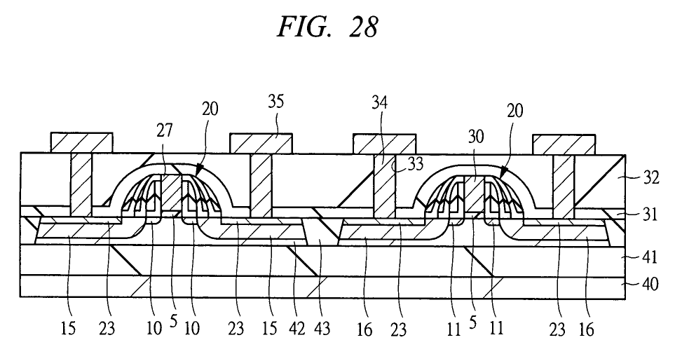

Subsequently, as shown in FIG. 28, the silicon gate electrodes 6a and 6b are silicided to form a gate electrode 27 formed of a nickel silicide film in an n channel MISFET forming region and a gate electrode 30 formed of a platinum silicide film in a p channel MISFET forming region, respectively. Therefore, in the same manner as that in the first embodiment, an wiring layer is formed. In this manner, a semiconductor device according to the second embodiment can be formed.

In the second embodiment, although the SOI substrate is used, it is possible to prevent the single crystal silicon layer 42 of the SOI substrate from being etched in the manufacturing process of a semiconductor device. For this reason, an extremely shallow source region and drain region can be formed in the very thin single crystal silicon layer 42. By forming the extremely shallow source region and drain region, a short channel effect can be suppressed. Therefore, according to the second embodiment, the device characteristics of the semiconductor device can be improved. Also, in the second embodiment, the same effect as that in the first embodiment can be obtained.

Further, in the second embodiment, the shallow n type impurity diffusion region 10 and the deep n type impurity diffusion region 15 are formed. However, it is not meant to be restrictive, and the second embodiment can also be applied to the case where one type of n type impurity diffusion regions are formed.

In the foregoing, the invention made by the inventors of the present invention has been concretely described based on the embodiments. However, it is needless to say that the present invention is not limited to the foregoing embodiments and various modifications and alterations can be made within the scope of the present invention.

The present invention can be widely used in manufacturing industries for manufacturing semiconductor devices.

What is claimed is:

1. A semiconductor device comprising:
a semiconductor substrate;
a gate insulating film formed on the semiconductor substrate;
a gate electrode formed on the gate insulating film; and
a sidewall formed on a sidewall of the gate electrode,
wherein the sidewall is formed of a laminated film of an aluminum oxide film and an insulating film, and the aluminum oxide film is in contact with the semiconductor substrate and the insulating film is not in contact with the semiconductor substrate.

2. The semiconductor device according to claim 1,
wherein the sidewall is formed of multiple layers in units of the laminated film.

3. The semiconductor device according to claim 2,
wherein the sidewall is formed of a laminated film of an aluminum oxide film and an insulating film, and an impurity diffusion region is formed in the semiconductor substrate in alignment with the laminated film.

4. The semiconductor device according to claim 2,
wherein the sidewall is formed of a first laminated film of an aluminum oxide film and an insulating film and a second laminated film of an aluminum oxide and an insulating film formed on the first laminated film, a shallow impurity diffusion region is formed in the semiconductor substrate in alignment with the first laminated film, and a deep impurity diffusion region in which an impurity is implanted more deeply than the shallow impurity diffusion region is formed in the semiconductor substrate in alignment with the second laminated film.

5. The semiconductor device according to claim 4,
wherein, on the sidewall, a third laminated film of an aluminum oxide film and an insulating film formed on the second laminated film is formed, and a metal silicide film is formed in the deep impurity diffusion region in alignment with the third laminated film.

6. The semiconductor device according to claim 1,
wherein the insulating film is formed on the aluminum oxide film.

7. The semiconductor device according to claim 1,
wherein the insulating film is a silicon nitride film.

8. The semiconductor device according to claim 1,
wherein the semiconductor substrate is an SOI substrate.

9. The semiconductor device according to claim 1,
wherein the gate insulating film is a high dielectric constant film having a dielectric constant higher than that of a silicon oxide film.

10. The semiconductor device according to claim 1,
wherein the gate electrode is formed of a metal film or a metal silicide film.

11. The semiconductor device according to claim 1,
wherein a gate length of the gate electrode is 20 nm or less.

12. The semiconductor device according to claim 1,
wherein a gate length of the gate electrode is 10 nm or less.

13. A manufacturing method of a semiconductor device comprising:
(a) a step of forming a gate insulating film on a semiconductor substrate;
(b) a step of forming a gate electrode on the gate insulating film; and
(c) a step of forming a sidewall on a sidewall of the gate electrode,
wherein the step (c) includes:
(c1) a step of forming an aluminum oxide film on the semiconductor substrate including the gate electrode;
(c2) a step of forming an insulating film on the aluminum oxide film;
(c3) a step of leaving the insulating film only on a sidewall of the gate electrode; and
(c4) a step of removing the aluminum oxide film exposed by performing the step (c3).

14. The manufacturing method of a semiconductor device according to claim 13,
wherein the step (c3) is performed by anisotropic dry etching, and the step (c4) is performed by wet etching.

15. The manufacturing method of a semiconductor device according to claim 14,
wherein the insulating film is a silicon nitride film.

16. The manufacturing method of a semiconductor device according to claim 13,
wherein the aluminum oxide film is formed by an ALD method in the step (c1).

17. The manufacturing method of a semiconductor device according to claim 16,
wherein the aluminum oxide film is formed at a temperature ranging from 100° C. to 500° C. in the step (c1).

18. The manufacturing method of a semiconductor device according to claim 16,
wherein the aluminum oxide film is formed at a temperature ranging from 200° C. to 300° C. in the step (c1).

19. The manufacturing method of a semiconductor device according to claim 13,
wherein the semiconductor substrate is an SOI substrate.

20. The manufacturing method of a semiconductor device according to claim 13,
wherein the gate insulating film is a high dielectric constant film having a dielectric constant higher than that of a silicon oxide film.

21. A manufacturing method of a semiconductor device comprising:
(a) a step of forming a gate insulating film on a semiconductor substrate;
(b) a step of forming a silicon gate electrode on the gate insulating film;
(c) a step of forming a first laminated film on a sidewall of the silicon gate electrode;
(d) a step of forming a shallow impurity diffusion region in the semiconductor substrate in alignment with the first laminated film;
(e) a step of forming a second laminated film on the first laminated film on the sidewall of the silicon gate electrode;
(f) a step of forming a deep impurity diffusion region in which an impurity is implanted more deeply than the shallow impurity diffusion region in the semiconductor substrate in alignment with the second laminated film;
(g) a step of forming a third laminated film on the second laminated film on the sidewall of the silicon gate electrode; and
(h) a step of forming a first metal silicide film in the deep impurity diffusion region in alignment with the third laminated film,
wherein each of the steps of forming the first laminated film, the second laminated film, and the third laminated film includes:
(i1) a step of forming an aluminum oxide film on the semiconductor substrate including a surface of the silicon gate electrode;
(i2) a step of forming a first insulating film on the aluminum oxide film;
(i3) a step of anisotropically dry-etching the first insulating film to leave the first insulating film only on a sidewall of the silicon gate electrode; and
(i4) a step of removing the aluminum oxide film exposed by the step (i3) by wet etching.

22. The manufacturing method of a semiconductor device according to claim 21, further comprising:
(j) a step of forming a second insulating film on the semiconductor substrate after the step (h);
(k) a step of exposing the silicon gate electrode on a surface of the second insulating film;
(l) a step of forming a metal film on the second insulating film including a surface of the silicon gate electrode; and
(m) a step of reacting the metal film with the silicon gate electrode to form a gate electrode formed of a second metal silicide film.

23. The manufacturing method of a semiconductor device according to claim 22,
wherein the first metal silicide film and the second metal silicide film are the same type of films.

24. The manufacturing method of a semiconductor device according to claim 22,
wherein, in the step (h), the first metal silicide film is formed also on the silicon gate electrode, and a gate electrode formed of the first metal silicide film is formed.
